(19) United States
(12) Patent Application Publication
(10) Pub. No.: US 2026/0110748 A1
(43) Pub. Date: Apr. 23, 2026

(54) BATTERY CELL MEASURING DEVICE

(71) Applicant: Samsung SDI Co., Ltd., Yongin-si (KR)

(72) Inventors: Seulong Choi, Yongin-si (KR); Dongsu Choi, Yongin-si (KR); Jang Hyo Lee, Yongin-si (KR)

(73) Assignee: Samsung SDI Co., Ltd., Yongin-si (KR)

(21) Appl. No.: 19/328,771

(22) Filed: Sep. 15, 2025

(30) Foreign Application Priority Data
Oct. 17, 2024 (KR) 10-2024-0141725

(51) Int. Cl. G01R 31/389; G01R 1/067; G01R 31/3835; G01R 31/396; H01M 10/42

(52) U.S. Cl. CPC G01R 31/389; G01R 1/06716; G01R 31/3835; G01R 31/396; H01M 10/4285

(57) ABSTRACT

A battery cell measuring device may include a plurality of measurement modules each measuring at least one of a resistance or a voltage of each of a plurality of battery cells. Each of the plurality of measurement modules may include a probe pin connected to the electrode terminal of one of the plurality of battery cells and configured to measure at least one of the resistance or the voltage of the battery cell, a bracket into and through which the probe pin is inserted and penetrates, a holder disposed on a lower surface of the bracket and surrounding at least a part of an outer surface of the probe pin protruding from a lower surface of the bracket, and a support disposed on an upper surface of the bracket to be connected to the measurement module plate and providing a path along which the measurement module plate moves vertically.

### CROSS-REFERENCE TO RELATED APPLICATIONS

This present application claims priority to and the benefit under 35 U.S.C. § 119(a)-(d) of Korean Patent Application No. 10-2024-0141725, filed on Oct. 17, 2024, in the Korean Intellectual Property Office, the entire disclosure of which is incorporated herein by reference.

### FIELD

The present disclosure relates to a device for measuring a voltage and a resistance of a battery cell.

### BACKGROUND

Unlike primary batteries that are not designed to be (re)charged, secondary (or rechargeable) batteries are batteries that are designed to be discharged and recharged. Low-capacity secondary batteries are used in portable, small electronic devices, such as smart phones, feature phones, notebook computers, digital cameras, and camcorders, while large-capacity secondary batteries are widely used as power sources for driving motors in hybrid vehicles and electric vehicles and for storing power (e.g., home and/or utility scale power storage). A secondary battery generally includes an electrode assembly composed of a positive electrode and a negative electrode, a case accommodating the same, and electrode terminals connected to the electrode assembly.

The above information disclosed in this Background section is for enhancement of understanding of the background of the present disclosure, and therefore, it may contain information that does not constitute related (or prior) art.

### SUMMARY

Some embodiments of the present disclosure provide a battery cell measuring device for solving one or more problems identified herein.

However, the technical problem to be solved by the present disclosure is not limited to the above problem, and other problems not mentioned herein, and aspects and features of the present disclosure that would address such problems, will be clearly understood by those skilled in the art from the description of the present disclosure below.

According to one or more embodiments of the present disclosure, a battery cell measuring device may include a plurality of measurement modules each measuring at least one of a resistance or a voltage of each of a plurality of battery cells, and a base frame including a measurement module plate configured to array the plurality of measurement modules at positions corresponding to electrode terminals of the plurality of battery cells. Each of the plurality of measurement modules may include a probe pin connected to the electrode terminal of one of the plurality of battery cells and configured to measure at least one of the resistance or the voltage of the battery cell, a bracket into and through which the probe pin is inserted and penetrates, a holder disposed on a lower surface of the bracket and surrounding at least a part of an outer surface of the probe pin protruding from a lower surface of the bracket, and a support disposed on an upper surface of the bracket to be connected to the measurement module plate, and providing a path along which the measurement module plate moves vertically.

According to one or more embodiments, the support may include an elastic member that reduces a pressure transmitted from the probe pin when the measurement module plate moves vertically such that the probe pin and the electrode terminal of the battery cell come into contact.

According to one or more embodiments, the holder may include a protrusion extending to protrude from a lower surface in a longitudinal direction of the probe pin, a through-hole formed in the protrusion, and a penetration guide pin disposed on an outer peripheral surface of the through-hole to surround an outer surface of the probe pin.

According to one or more embodiments, the bracket may include a first magnet, the holder may include a second magnet having an opposite polarity to the first magnet, and the first magnet and the second magnet may come into contact with each other by mutual attraction to connect the bracket and the holder.

According to one or more embodiments, the battery cell measuring device may further include a first bolt that fixes the first magnet on the bracket, and a second bolt that fixes the second magnet on the holder.

According to one or more embodiments, the battery cell measuring device may further include a fixing pin that penetrates through the bracket to be inserted into one surface of the holder, and a third bolt that penetrates the other surface of the holder to be coupled with the fixing pin.

According to one or more embodiments, the support may include a guide column having a lower end connected to the bracket, a spring surrounding a side surface of the guide column, and a plate fastening portion disposed at an upper end of the guide column and fastened to the measurement module plate to move vertically.

According to one or more embodiments, the plate fastening portion may include an insertion portion into which the measurement module plate is inserted, and a flange protruding in a radial direction of the insertion portion.

According to one or more embodiments, the battery cell measuring device may further include a first fixing portion disposed on the bracket and including a groove into which one end of the spring is fixedly inserted, and a second fixing portion disposed on the plate fastening portion and including a groove into which the other end of the spring is fixedly inserted.

According to one or more embodiments, the spring may be a compression spring compressible as the measurement module plate moves vertically.

According to one or more embodiments, the support may include a plurality of supports disposed on the bracket.

According to one or more embodiments, the plurality of supports may be disposed in corner regions of the bracket, respectively.

According to one or more embodiments, the probe pin may include an electrode terminal portion that comes into contact with the electrode terminal of the battery cell, a compression spring that provides an elastic force to the electrode terminal portion, a body portion that is fixedly inserted into the bracket, and a cable terminal portion that is connected to a cable.

According to one or more embodiments, when the probe pin may be pressurized while coming into contact with the electrode terminal of the battery cell, the electrode terminal portion may be inserted into the penetration guide pin of the holder by being compressed by the compression spring.

According to one or more embodiments, one surface of the bracket may be dented so as to correspond to one side surface of the holder. The battery cell measuring device further may include a fixing member disposed on the dented one surface of the bracket and the one side surface of the holder, and an index plunger that penetrates through the fixing member and the one side surface of the holder to apply a pressure to the probe pin.

According to one or more embodiments of the present disclosure, a battery cell measuring device may include a plurality of measurement modules each measuring at least one of a resistance or a voltage of each of a plurality of battery cells, a first frame including a measurement module plate configured to array the plurality of measurement modules at positions corresponding to electrode terminals of the plurality of battery cells, and a second frame connected to an upper portion of the first frame and moving the first frame such that the plurality of measurement modules corresponding to the plurality of battery cells come into contact with each other. each of the plurality of measurement modules may include a probe pin connected to the electrode terminal of one of the plurality of battery cells and configured to measure at least one of the resistance or the voltage of the battery cell, a bracket into and through which the probe pin is inserted and penetrates, a holder disposed on a lower surface of the bracket and surrounding at least a part of an outer surface of the probe pin protruding from a lower surface of the bracket, and a support disposed on an upper surface of the bracket to be connected to the measurement module plate, and provides a path along which the measurement module plate moves vertically.

According to one or more embodiments, the battery cell measuring device may further include a battery transport unit that aligns and disposes the plurality of battery cells at a plurality of predetermined positions, and transports the plurality of battery cells in one direction.

According to one or more embodiments, when the measurement module plate may move vertically such that the probe pin and the electrode terminal of the battery cell come into contact, the support may include an elastic member that reduces a pressure transmitted from the probe pin.

According to one or more embodiments, the bracket may include a first magnet, the holder may include a second magnet having an opposite polarity to the first magnet, and the first magnet and the second magnet may come into contact with each other by mutual attraction to connect the bracket and the holder.

According to one or more embodiments, the support may include a guide column having a lower end connected to the bracket, a spring surrounding a side surface of the guide column, and a plate fastening portion disposed at an upper end of the guide column and fastened to the measurement module plate to move vertically.

According to some embodiments of the present disclosure, in the battery cell measuring device, twisting of the probe pin that may occur in a procedure of bringing the probe pin into contact with the electrode terminal can be prevented by using the configuration for fixing the probe pin while surrounding the outer surface of the protruding probe pin.

According to some embodiments of the present disclosure, the probe pin can be prevented from being twisted, and thus, the probe pin and the electrode terminal can be brought into constant contact with each other at a specific point. Accordingly, the dispersion of the measured voltage and resistance values can be reduced.

According to some embodiments of the present disclosure, in a procedure of bringing the probe pin into contact with the electrode terminal, the elastic force that reduces the pressure transmitted to the probe pin is provided, and thus, the probe pin can be prevented from being broken.

However, aspects and features of the present disclosure are not limited to those described herein, and other aspects and features not mentioned will be clearly understood by a person skilled in the art from the detailed description, described below.

### BRIEF DESCRIPTION OF THE DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings.

FIG. 1 is a diagram illustrating a battery cell measuring device according to some embodiments of the present disclosure.

FIG. 2 is a diagram illustrating the battery cell measuring device illustrated in FIG. 1 as viewed from a Y-axis.

FIG. 3 is a diagram illustrating the battery cell measuring device according to some embodiments of the present disclosure.

FIG. 4 is a diagram illustrating a scene in which a region A of FIG. 3 is viewed from above.

FIG. 5 is a diagram illustrating a scene in which the battery cell measuring device and a battery cell come into contact with each other according to some embodiments of the present disclosure.

FIG. 6 is a diagram illustrating the measurement module according to some embodiments of the present disclosure.

FIG. 7 is a diagram illustrating a scene in which the measurement module illustrated in FIG. 6 is viewed from the X-axis direction.

FIG. 8 is a diagram illustrating an example in which the measurement module illustrated in FIG. 7 and a cable are connected.

FIG. 9 is an exploded perspective view of a bracket and a holder of the measurement module illustrated in FIG. 6.

FIG. 10 is a diagram illustrating a section taken along line B-B in FIG. 6.

FIG. 11 is an exploded perspective view of an index plunger of the measurement module illustrated in FIG. 6.

FIG. 12 is a diagram illustrating a probe pin according to some embodiments of the present disclosure.

FIG. 13 is a diagram illustrating a scene in which the plurality of measurement modules and the plurality of battery cells come into contact with each other according to some embodiments of the present disclosure.

FIGS. 14 to 16 are diagrams illustrating a series of procedures in which the measurement module according to some embodiments of the present disclosure comes into contact with the battery cell.

### DETAILED DESCRIPTION

Hereinafter, embodiments of the present disclosure will be described, in detail, with reference to the accompanying drawings. The terms or words used in the present specification and claims are not to be limitedly interpreted as general or dictionary meanings and should be interpreted as meanings and concepts that are consistent with the technical idea of the present disclosure on the basis of the principle that an inventor can be his/her own lexicographer to appropriately define concepts of terms to describe his/her invention in the best way.

The embodiments described in this specification and the configurations shown in the drawings are only some of the embodiments of the present disclosure and do not represent all of the technical spirit, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. §112(a) and 35 U.S. C. § 132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

After secondary batteries are manufactured, quality testing may be performed. The quality testing may be performed by measuring an open circuit voltage and an internal resistance of each battery cell by using a battery cell measuring device. A probe pin may be provided in the battery cell measuring device, and may measure the open circuit voltage and the internal resistance by bringing the probe pin into contact with an electrode terminal of the battery cell. The probe pin may be brought into contact with the electrode terminal by pressurizing the electrode terminal such that the probe pin and the electrode terminal come into contact with each other without being misaligned. However, the probe pin may be broken in a procedure of pressurizing the probe pin.

Some embodiments of the present disclosure provide a battery cell measuring device for solving one or more problems identified herein.

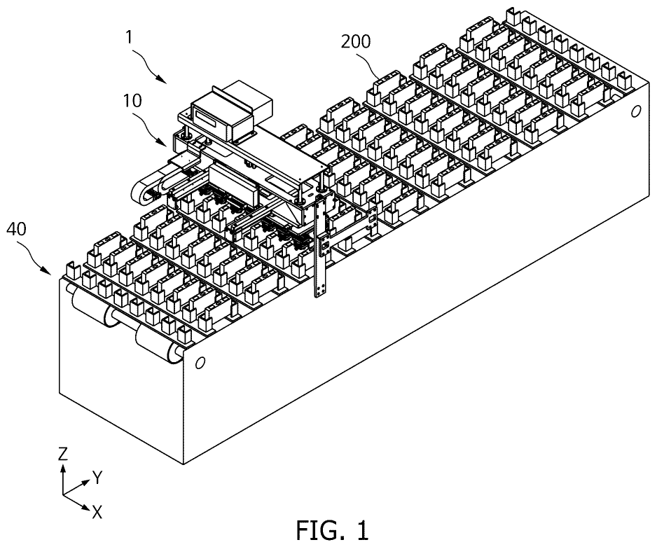

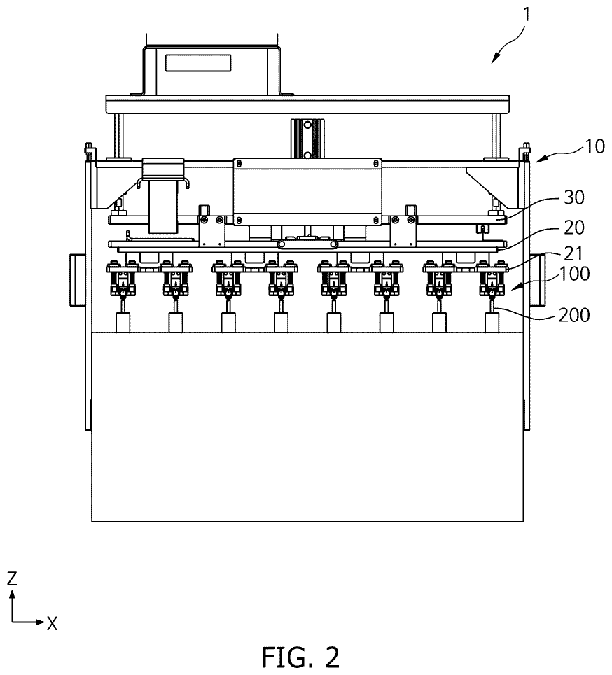

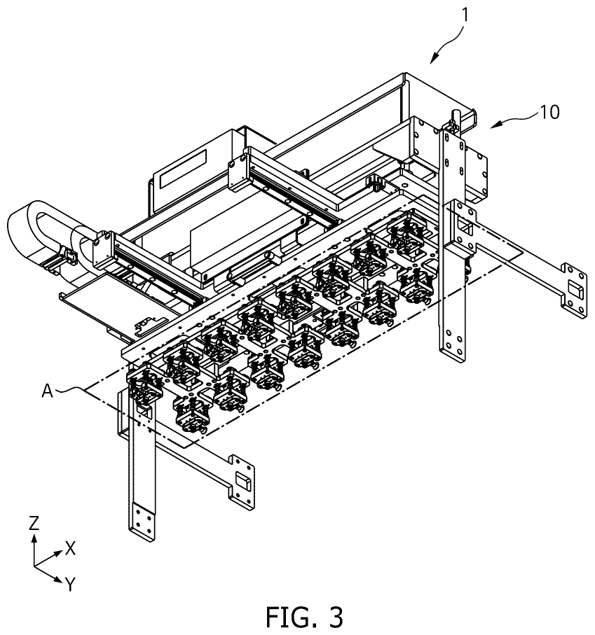

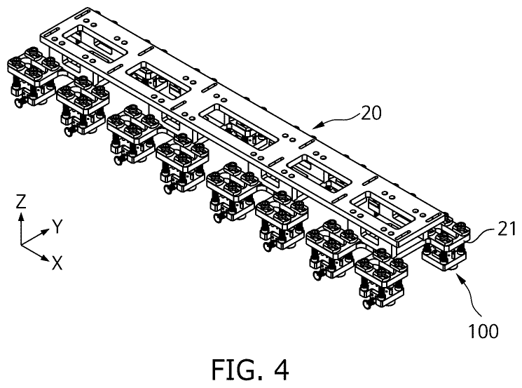

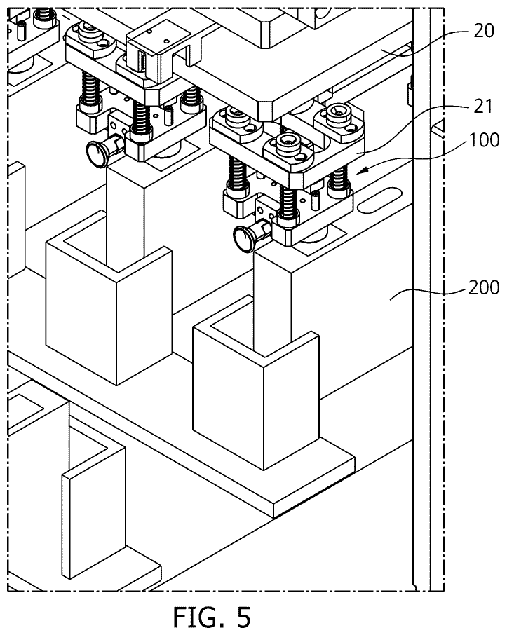

FIG. 1 is a diagram illustrating a battery cell measuring device according to some embodiments of the present disclosure. FIG. 2 is a diagram illustrating the battery cell measuring device illustrated in FIG. 1 as viewed from a Y-axis. FIG. 3 is a diagram illustrating the battery cell measuring device according to some embodiments of the present disclosure. FIG. 4 is a diagram illustrating a scene in which a region A of FIG. 3 is viewed from above. FIG. 5 is a diagram illustrating a scene in which the battery cell measuring device and a battery cell come into contact with each other according to some embodiments of the present disclosure.

Referring to FIGS. 1 to 5, a battery cell measuring device 1 according to some embodiments of the present disclosure may include a battery transport unit 40, a base frame 10, and a plurality of measurement modules 100.

According to some embodiments, the battery transport unit 40 may align and dispose a plurality of battery cells 200 at a plurality of predetermined positions, and may transport the plurality of battery cells 200 in one direction. For example, the battery transport unit 40 may transport the plurality of battery cells 200 in one direction (Y-axis direction) after inserting and fixing the battery cells to a fixing member arrayed or arranged in a row (X-axis direction). The battery transport unit 40 may include a conveyor for transporting the battery cells 200, a fixing member for fixing the battery cells 200 on the conveyor, a drive unit for providing power to the conveyor, and the like. For example, the partibattery cell 200 may be, but is not limited to, a square secondary battery, and may be other types of batteries such as a cylindrical battery, a pouch-type battery, and the like. However, for the sake of simplicity in description, the following description focuses on the pouch-type battery.

According to some embodiments, the base frame 10 may be disposed on the battery transport unit 40. For example, support bars may be installed on both side surfaces of the battery transport unit 40, and the base frame 10 may be connected to the support bars while being separated from the battery transport unit 40. The plurality of battery cells 200 transported by the battery transport unit 40 may pass through the base frame 10.

According to some embodiments, the battery transport unit 40 may temporarily stop the transport of the battery cells 200 when the plurality of battery cells 200 are transported and disposed vertically with respect to the base frame 10. Thereafter, after at least one of a voltage or a resistance of each of the battery cells 200 is measured by each of the measurement modules 100 disposed on the base frame 10, the battery transport unit 40 may transport the battery cells 200. For example, the battery transport unit 40 may transport a plurality of battery cells 200 aligned in a first row of the conveyor so as to be disposed vertically with respect to the base frame 10, and then may stop the battery cells. In some embodiments, after each of the plurality of measurement modules 100 connected to the base frame 10 measures at least one of the voltage or resistance of each of the battery cells 200, the battery transport unit 40 may transport the plurality of battery cells 200 aligned in the first row forward (Y-axis direction) and may simultaneously transport a plurality of battery cells 200 aligned in a second row of the conveyor so as to be disposed vertically with respect to the base frame 10. Such a procedure of transporting and testing the battery cells 200 may be repeated until testing is completed on all the battery cells 200 arrayed or arranged on the battery transport unit 40. However, the method for transporting and testing the plurality of battery cells 200 described herein is only an example, and the present disclosure is not limited thereto.

According to some embodiments, the base frame 10 may include a measurement module plate 21 configured to dispose the plurality of measurement modules 100 at positions corresponding to electrode terminals of the plurality of battery cells 200. The plurality of measurement modules 100 can be disposed on the measurement module plate 21. The plurality of measurement modules 100 may come into contact with or may be connected to the electrode terminals of the plurality of battery cells 200 transported by the battery transport unit 40 to measure at least one of the voltages or resistances of the corresponding battery cells.

According to some embodiments, the base frame 10 may include a first frame 20, a second frame 30, a drive unit, a control unit, and the like.

According to some embodiments, the first frame 20 may be connected to one side surface of the measurement module plate 21 configured to dispose the plurality of measurement modules 100 at the positions corresponding to the electrode terminals of the plurality of battery cells 200. The plurality of measurement modules 100 may be disposed on the other side surface of the measurement module plate 21. The first frame 20 may move vertically by the second frame 30.

According to some embodiments, the second frame 30 may be connected to an upper portion of the first frame 20 and may move the first frame 20 such that the plurality of battery cells 200 and the plurality of corresponding measurement modules 100 come into contact with each other.

For example, the first frame 20 may move vertically while being connected to a vertical motor and/or a hydraulic cylinder installed in the second frame 30, but is not limited thereto. The second frame 30 may vertically move the first frame 20 such that the plurality of measurement modules 100 disposed vertically to be separated from the plurality of battery cells 200 come into contact with the battery cells 200.

According to some embodiments, the second frame 30 may move in response to a state where the plurality of battery cells 200 are arrayed in the battery transport unit 40. For example, the second frame 30 may be connected to a linear motor to move in a direction (Y-axis direction) in which the plurality of battery cells 200 are transported or in a direction perpendicular to a transport direction (X-axis direction), but is not limited thereto.

According to some embodiments, the drive unit may provide power to move the first frame 20 and the second frame 30. For example, the drive unit may include, but is not limited to, a vertical motor, a linear motor, a hydraulic cylinder, and the like, and may be various types of drive devices capable of moving the first frame 20 and the second frame 30. The control unit may control an operation of the drive unit. For example, the control unit may receive information about the array state of the plurality of battery cells 200 and may control the operation of the drive unit.

According to some embodiments, the plurality of measurement modules 100 may be disposed on the measurement module plate 21 connected to the first frame 20. The plurality of measurement modules 100 may be disposed on a lower surface of the measurement module plate 21 so as to correspond to positions of some of the plurality of battery cells 200 arrayed in the battery transport unit 40. For example, the plurality of measurement modules 100 may be disposed on the lower surface of the measurement module plate 21 so as to correspond to the position of the fixing member that fixes the battery cells 200 on the conveyor of the battery transport unit 40.

As illustrated in FIG. 5, as the first frame 20 moves vertically, the plurality of measurement modules 100 are lowered vertically to come into contact with the electrode terminals of the plurality of battery cells 200 disposed in the battery transport unit 40. As a result, at least one of the voltages or resistances of the corresponding battery cells may be measured. For example, each of the plurality of measurement modules 100 may come into contact with the electrode terminals of the battery cells 200 to measure open circuit voltages or internal resistances of the battery cells 200.

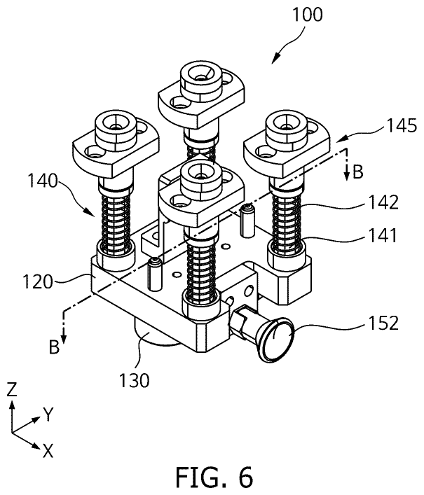

A specific description of the method for connecting the plurality of measurement modules 100 to the measurement module plate 21 will be described herein with reference to FIGS. 6 to 12.

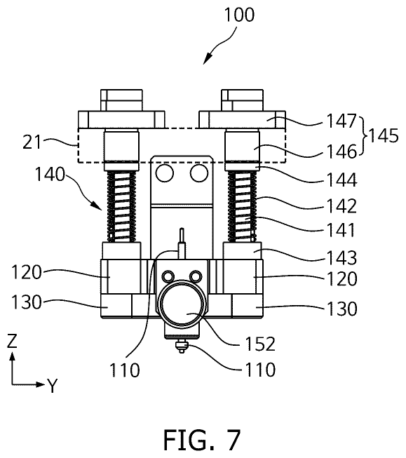

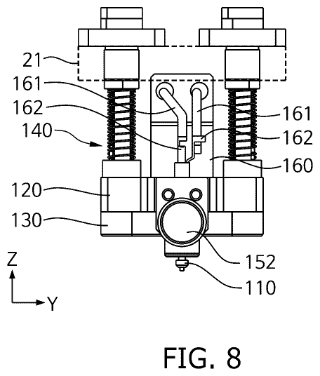

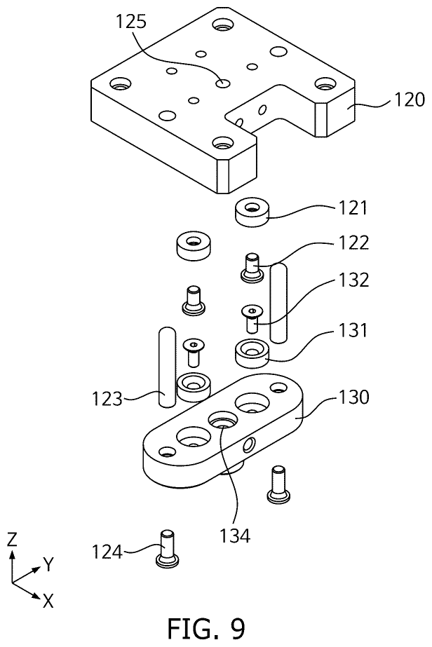

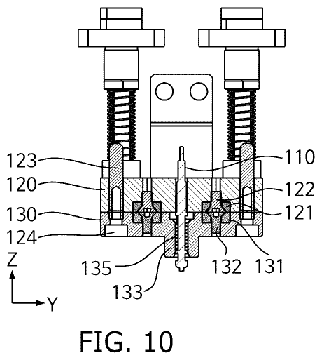

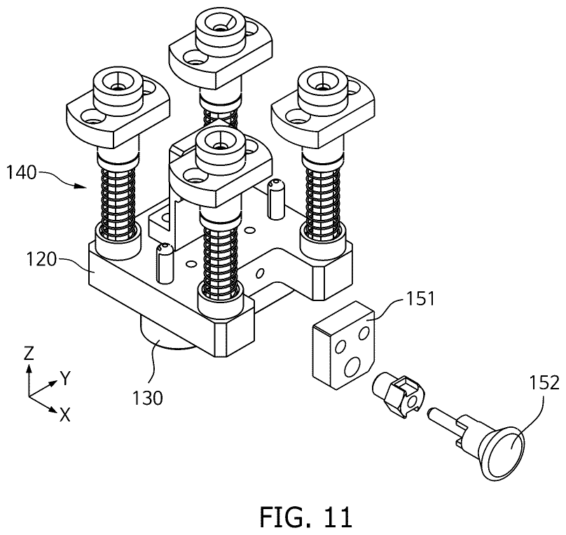

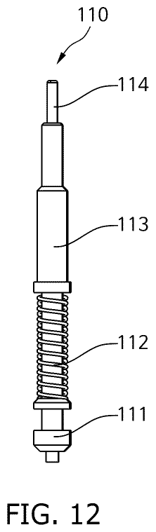

FIG. 6 is a diagram illustrating the measurement module according to some embodiments of the present disclosure. FIG. 7 is a diagram illustrating a scene in which the measurement module illustrated in FIG. 6 is viewed from the X-axis direction. FIG. 8 is a diagram illustrating an example in which the measurement module illustrated in FIG. 7 and a cable are connected. FIG. 9 is an exploded perspective view of a bracket and a holder of the measurement module illustrated in FIG. 6. FIG. 10 is a diagram illustrating a section taken along line B-B in FIG. 6. FIG. 11 is an exploded perspective view of an index plunger of the measurement module illustrated in FIG. 6. FIG. 12 is a diagram illustrating a probe pin according to some embodiments of the present disclosure.

Referring to FIGS. 6 to 12, each of the plurality of measurement modules 100 according to some embodiments of the present disclosure may include a probe pin 110 connected to the electrode terminal of one of the plurality of battery cells 200 (see e.g., FIG. 5) and configured to measure at least one of the resistance or voltage of the battery cell 200, a bracket 120 into and/or through which the probe pin 110 is inserted and penetrates, a holder 130 disposed on a lower surface of the bracket 120 to surround at least a part of an outer surface of the probe pin 110 protruding from the lower surface of the bracket 120, and a support 140 disposed on an upper surface of the bracket 120 to be connected to the measurement module plate 21, and provides a path along which the measurement module plate 21 moves vertically.

According to some embodiments, the support 140 may include an elastic member that reduces a pressure transmitted from the probe pin 110 when the measurement module plate 21 moves vertically such that the probe pin 110 and the electrode terminal of the battery cell 200 come into contact with each other. The elastic member may be, but is not limited to, a spring.

As illustrated in FIGS. 7 and 8, the probe pin 110 may come into contact with the electrode terminal of the battery cell 200 as the measurement module plate 21 is lowered vertically. The probe pin 110 may penetrate through the bracket 120 and the holder 130. At least a part of the outer surface of the probe pin 110 protruding from the lower surface of the bracket 120 (one surface in a direction opposite to the Z-axis) may be surrounded by the holder 130. The probe pin 110 protruding from the upper surface (Z-axis direction) of the bracket 120 may be connected to a cable 161 through a cable connector 162.

Each of the plurality of measurement modules 100 may further include a cable holder 160 for fixing the cable 161 connected to the probe pin 110. The cable holder 160 may be disposed on the bracket 120. For example, the cable holder 160 includes a hole formed at an upper end, and the cable 161 may penetrate through the hole to be fixedly connected to the probe pin 110.

The probe pin 110 may be inserted into and may penetrate through the bracket 120. The bracket 120 may include a through-hole 125 through which the probe pin 110 penetrates. The holder 130 may be disposed on the lower surface of the bracket 120 (one surface in the direction opposite to the Z-axis). The support 140 may be disposed on the upper surface of the bracket 120 (one surface in the Z-axis direction).

The holder 130 may be disposed on the lower surface of the bracket 120 and may surround at least a part of the outer surface of the probe pin 110 protruding from the lower surface of the bracket 120. The holder 130 may include a protrusion 133 that extends to protrude from a lower surface in a longitudinal direction of the probe pin 110, a through-hole 134 formed in the protrusion 133, and a penetration guide pin 135 that is disposed on an outer peripheral surface of the through-hole 134 and surrounds the outer surface of the probe pin 110.

Referring to FIGS. 9 and 10, the bracket 120 may include a first magnet 121 and a first bolt 122. The first magnet 121 may be disposed in a groove formed on the lower surface of the bracket 120 (one surface in the direction opposite to the Z-axis). A hole may be formed in the groove of the bracket 120 in which the first magnet 121 is disposed. A hole may be formed in the first magnet 121 so as to correspond to the hole formed in the groove of the bracket 120. The first bolt 122 may fixedly dispose (e.g., fix) the first magnet 121 on the bracket 120. The first bolt 122 may be inserted into the hole of the first magnet 121 and the hole formed in the groove of the bracket 120, and thus, the first magnet 121 may be fixedly disposed on the bracket 120.

The holder 130 may include a second magnet 131 having an opposite polarity to the first magnet 121 and a second bolt 132. The second magnet 131 may be disposed in a groove formed on an upper surface of the holder 130 (one surface in the Z-axis direction). A hole may be formed in the groove of the holder 130 in which the second magnet 131 is disposed. A hole may be formed in the second magnet 131 to correspond to the hole formed in the groove of the holder 130. The second bolt 132 may fixedly dispose the second magnet 131 on the holder 130. The second bolt 132 may be inserted into the hole of the second magnet 131 and the hole formed in the groove of the holder 130, and thus, the second magnet 131 may be fixedly disposed on the holder 130.

The first magnet 121 disposed on the lower surface of the bracket 120 and the second magnet 131 disposed on the upper surface of the holder 130 come into contact with each other by mutual attraction, and may connect the bracket 120 and the holder 130.

Each of the plurality of measurement modules 100 may further include a fixing pin 123 that penetrates through the bracket 120 to be inserted into one surface (upper surface) of the holder 130 and a third bolt 124 that penetrates through the other surface (lower surface) of the holder 130 to be coupled with the fixing pin 123.

The first magnet 121, the second magnet 131 and the fixing pin 123 may fix the holder 130 disposed on the lower surface of the bracket 120.

The support 140 may be disposed on the upper surface of the bracket 120 to be connected to the measurement module plate 21, and may provide a path along which the measurement module plate 21 moves vertically.

The support 140 may include a plurality of supports 140 disposed on the bracket 120. For example, the plurality of supports 140 may be disposed in corner regions of the bracket 120, respectively, but are not limited thereto.

The support 140 may include a guide column 141 having a lower end connected to the bracket 120, a spring 142 surrounding a side surface of the guide column 141, and a plate fastening portion 145 disposed at an upper end of the guide column 141 and fastened to the measurement module plate 21 to move vertically.

The plate fastening portion 145 may include an insertion portion 146 into which the measurement module plate 21 is inserted, and a flange 147 that protrudes in a radial direction of the insertion portion 146. A hole may be formed in the flange 147 to be bolt-fastened to the measurement module plate 21. For example, the measurement module plate 21 may be inserted into the insertion portion 146 of the support 140, and then may be fixed by being bolt-fastened to the flange 147.

The guide column 141 may provide a path along which the measurement module plate 21 moves vertically. The spring 142 surrounding the side surface of the guide column 141 may be a compressible spring as the measurement module plate 21 moves vertically.

The support 140 may further include a first fixing portion 143 disposed on the bracket 120 and including a groove into which one end of the spring 142 is fixedly inserted, and a second fixing portion 144 disposed on the plate fastening portion 145 and including a groove into which the other end of the spring 142 is fixedly inserted. The spring 142 may be compressed between the first fixing portion 143 and the second fixing portion 144.

As illustrated in FIG. 11, each of the plurality of measurement modules 100 may include a fixing member 151 and an index plunger 152. One surface of the bracket 120 may be dented so as to correspond to one side surface of the holder 130. The fixing member 151 may be disposed on one dented side surface of the bracket 120 and one side surface of the holder 130. The index plunger 152 may penetrate through the fixing member 151 and one side surface of the holder 130 to apply a pressure to the probe pin 110.

As illustrated in FIG. 12, the probe pin 110 may include an electrode terminal portion 111 that comes into contact with the electrode terminal of the battery cell, a compression spring 112 that provides an elastic force to the electrode terminal portion 111, a body portion 113 that is fixedly inserted into the bracket 120, and a cable terminal portion 114 that is connected to the cable 161.

When the probe pin 110 is pressurized while coming into contact with the electrode terminal of the battery cell, the compression spring 112 may be compressed. The electrode terminal portion 111 may be inserted into the penetration guide pin 135 (see e.g., FIG. 10) of the holder 130 by being compressed by the compression spring 112. The electrode terminal portion 111 may come into contact with the electrode terminal of the battery cell 200 in a state of being inserted into the penetration guide pin 135 of the holder 130, and thus, the probe pin 110 may be prevented from being twisted.

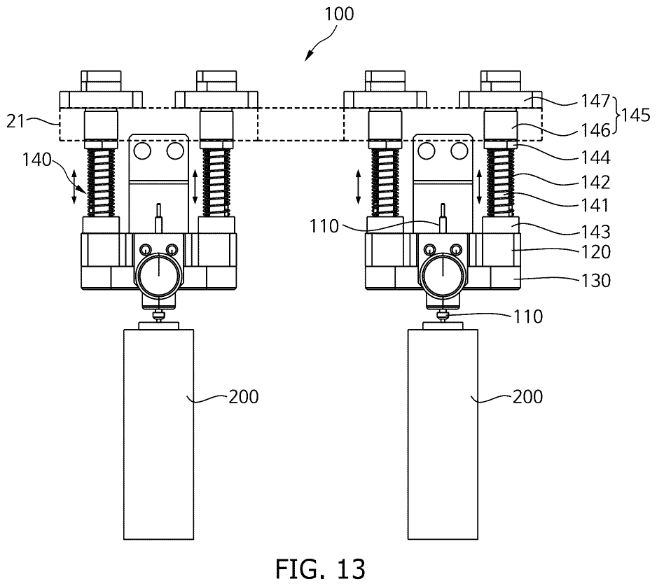

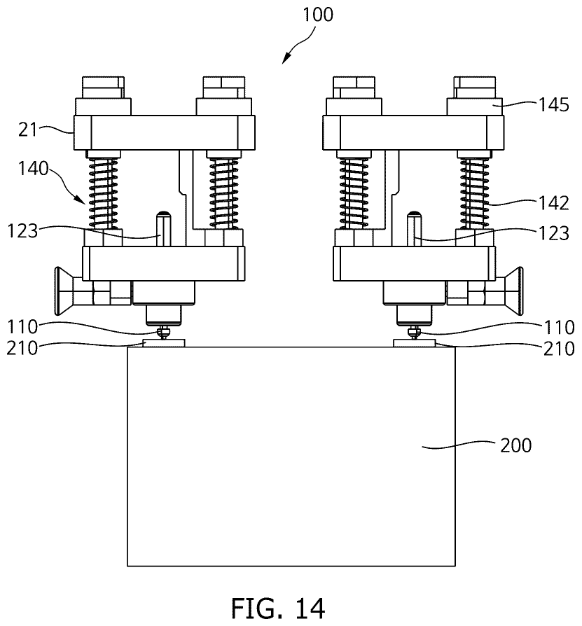

FIG. 13 is a diagram illustrating a scene in which the plurality of measurement modules and the plurality of battery cells come into contact with each other according to some embodiments of the present disclosure. FIGS. 14 to 16 are diagrams illustrating a series of procedures in which the measurement module according to some embodiments of the present disclosure comes into contact with the battery cell.

Referring to FIG. 13, each of the plurality of measurement modules 100 may measure at least one of the voltage or the resistance while coming into contact with each of the plurality of battery cells 200. As the measurement module plate 21 moves vertically, each of the plurality of measurement modules 100 may come into contact with each of the plurality of battery cells 200.

Referring to FIG. 14, as the measurement module plate 21 is lowered vertically, the probe pin 110 of the measurement module 100 may come into contact with an electrode terminal 210 of the battery cell 200. The probe pin 110 of the measurement module 100 comes into contact with the electrode terminal 210 of the battery cell 200. At least one of the open circuit voltage and internal resistance of the battery cell 200 may be measured.

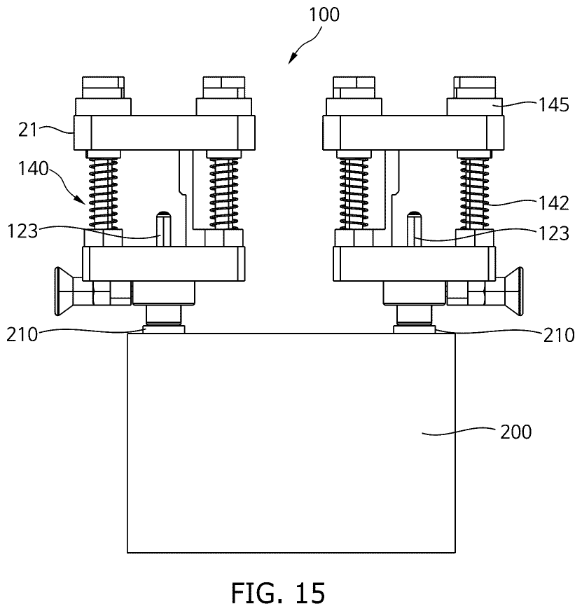

Referring to FIG. 15, in order to prevent the probe pin 110 coming into contact with the electrode terminal 210 from being misaligned in a procedure of measuring the voltage and resistance of the battery cell 200, the measurement module 100 may further pressurize the probe pin 110 toward the electrode terminal 210. When the probe pin 110 is pressurized, the electrode terminal portion 111 (see e.g., FIG. 12) of the probe pin 110 may be inserted into the penetration guide pin 135 (see e.g., FIG. 10) of the holder 130. The electrode terminal portion 111 may come into contact with the electrode terminal 210 in a state of being inserted into the penetration guide pin 135.

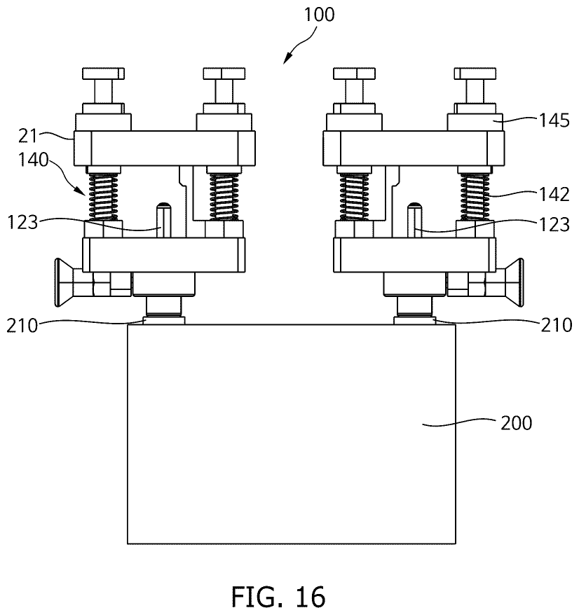

Referring to FIG. 16, in order to bring the probe pin 110 and the electrode terminal 210 into closer contact, the measurement module plate 21 may be lowered more vertically. The measurement module plate 21 is lowered vertically, and thus, the probe pin 110 may come into closer contact with the electrode terminal 210. The pressure transmitted to the probe pin 110 due to the vertical lowering of the measurement module plate 21 may be reduced by the elastic force of the spring 142 included in the support 140.

Although the present disclosure has been described above with respect to embodiments thereof, the present disclosure is not limited thereto. Various modifications and variations can be made thereto by those skilled in the art within the spirit of the present disclosure and the equivalent scope of the appended claims.

What is claimed is:

1. A battery cell measuring device comprising:
a plurality of measurement modules each configured to measure at least one of a resistance or a voltage of each of a plurality of battery cells; and
a base frame including a measurement module plate configured to arrange the plurality of measurement modules at positions corresponding to electrode terminals of the plurality of battery cells,
wherein each of the plurality of measurement modules includes:
a probe pin connected to the electrode terminal of a battery cell of the plurality of battery cells and configured to measure at least one of the resistance or the voltage of the battery cell,
a bracket into which the probe pin is inserted and through which the probe pin penetrates,
a holder disposed on a lower surface of the bracket and surrounding at least a part of an outer surface of the probe pin protruding from the lower surface of the bracket, and
a support disposed on an upper surface of the bracket to be connected to the measurement module plate and providing a path along which the measurement module plate moves vertically.

2. The battery cell measuring device according to claim 1, wherein the support includes an elastic member that reduces a pressure transmitted from the probe pin when the measurement module plate moves vertically such that the probe pin and the electrode terminal of the battery cell come into contact.

3. The battery cell measuring device according to claim 1,
wherein the holder includes:
a protrusion extending to protrude from a lower surface of the holder in a longitudinal direction of the probe pin,
a through-hole formed in the protrusion, and
a penetration guide pin disposed on an outer peripheral surface of the through-hole to surround an outer surface of the probe pin.

4. The battery cell measuring device according to claim 1, wherein:
the bracket includes a first magnet,
the holder includes a second magnet having an opposite polarity to the first magnet, and
the first magnet and the second magnet come into contact with each other by mutual attraction to connect the bracket and the holder.

5. The battery cell measuring device according to claim 4, further comprising:
a first bolt that fixes the first magnet on the bracket; and
a second bolt that fixes the second magnet on the holder.

6. The battery cell measuring device according to claim 1, further comprising:
a fixing pin that penetrates through the bracket to be inserted into one surface of the holder; and
a third bolt that penetrates another surface of the holder to be coupled with the fixing pin.

7. The battery cell measuring device according to claim 1,
wherein the support includes:
a guide column having a lower end connected to the bracket,
a spring surrounding a side surface of the guide column, and
a plate fastening portion disposed at an upper end of the guide column and fastened to the measurement module plate to move vertically.

8. The battery cell measuring device according to claim 7,
wherein the plate fastening portion includes:
an insertion portion into which the measurement module plate is inserted, and
a flange protruding in a radial direction of the insertion portion.

9. The battery cell measuring device according to claim 7, further comprising:
a first fixing portion disposed on the bracket and including a groove into which one end of the spring is fixedly inserted; and
a second fixing portion disposed on the plate fastening portion and including a groove into which another end of the spring is fixedly inserted.

10. The battery cell measuring device according to claim 7, wherein the spring is a compression spring that is compressible as the measurement module plate moves vertically.

11. The battery cell measuring device according to claim 1, wherein the support includes a plurality of supports disposed on the bracket.

12. The battery cell measuring device according to claim 11, wherein the plurality of supports are disposed in corner regions of the bracket, respectively.

13. The battery cell measuring device according to claim 1,
wherein the probe pin includes:
an electrode terminal portion that comes into contact with the electrode terminal of the battery cell,
a compression spring that provides an elastic force to the electrode terminal portion,
a body portion that is fixedly inserted into the bracket, and
a cable terminal portion that is connected to a cable.

14. The battery cell measuring device according to claim 13, wherein, when the probe pin is pressurized while coming into contact with the electrode terminal of the battery cell, the electrode terminal portion is inserted into the penetration guide pin of the holder by being compressed by the compression spring.

15. The battery cell measuring device according to claim 1,
wherein one surface of the bracket is dented so as to correspond to one side surface of the holder, and
wherein the battery cell measuring device further includes:
a fixing member disposed on the dented one surface of the bracket and the one side surface of the holder, and
an index plunger that penetrates through the fixing member and the one side surface of the holder to apply a pressure to the probe pin.

16. A battery cell measuring device comprising:
a plurality of measurement modules each configured to measure at least one of a resistance or a voltage of each of a plurality of battery cells;
a first frame including a measurement module plate configured to arrange the plurality of measurement modules at positions corresponding to electrode terminals of the plurality of battery cells; and
a second frame connected to an upper portion of the first frame and configured to move the first frame such that the plurality of measurement modules corresponding to the plurality of battery cells come into contact with each other,
wherein each of the plurality of measurement modules includes:
a probe pin connected to the electrode terminal of a battery cell of the plurality of battery cells and configured to measure at least one of the resistance or the voltage of the battery cell,
a bracket into which the probe pin is inserted and through which the probe pin penetrates,
a holder disposed on a lower surface of the bracket and surrounding at least a part of an outer surface of the probe pin protruding from the lower surface of the bracket, and
a support disposed on an upper surface of the bracket to be connected to the measurement module plate and providing a path along which the measurement module plate moves vertically.

17. The battery cell measuring device according to claim 16, further comprising:
a battery transport unit that aligns and disposes the plurality of battery cells at a plurality of predetermined positions and transports the plurality of battery cells in one direction.

18. The battery cell measuring device according to claim 16, wherein the support includes an elastic member such that when the measurement module plate moves vertically such that the probe pin and the electrode terminal of the battery cell come into contact, the elastic member reduces a pressure transmitted from the probe pin.

19. The battery cell measuring device according to claim 16, wherein:
the bracket includes a first magnet,
the holder includes a second magnet having an opposite polarity to the first magnet, and
the first magnet and the second magnet come into contact with each other by mutual attraction to connect the bracket and the holder.

20. The battery cell measuring device according to claim 16,
wherein the support includes:
a guide column having a lower end connected to the bracket,
a spring surrounding a side surface of the guide column, and
a plate fastening portion disposed at an upper end of the guide column and fastened to the measurement module plate to move vertically.
